(19) United States
(12) Patent Application Publication
(10) Pub. No.: US 2015/0263187 A1
(43) Pub. Date: Sep. 17, 2015

(54) PROTECTIVE FILM FOR USE WITH SOLAR CELL AND THE SOLAR CELL

(71) Applicant: MING-HUEI TECH CO., LTD, Hemei Township (TW)

(72) Inventor: YEN-CHI CHEN, HEMEI TOWNSHIP (TW)

(73) Assignee: MING-HUEI TECH CO., LTD, Hemei Township (TW)

(21) Appl. No.: 14/208,868

(22) Filed: Mar. 13, 2014

(51) Int. Cl. H01L 31/0216

(52) U.S. Cl. CPC H01L 31/02167

(57) ABSTRACT

A protective film for use with a solar cell and the solar cell are introduced. The protective film is a protective coating formed on an anti-reflection layer of the solar cell. The protective film is characterized in that the protective coating is made of an organic material or a phosphor-containing organic material. Accordingly, the protective film dispenses with the need to make any change to a conventional solar cell-related semiconductor manufacturing process but only requires mixing the constituent ingredients of a material of which the protective coating on the anti-reflection layer is made, so as to enable ultraviolet to be partially converted into absorbable light and thus enhance the photovoltaic conversion efficiency.

### FIELD OF TECHNOLOGY

The present invention relates to technology pertaining to solar cells, and more particularly, to a protective film for use with a solar cell and the solar cell with the protective film.

### BACKGROUND

Solar cells are regarded as one of the automatic, green, and clean energy sources. A solar cell typical contains a semiconductor material for use in generating electrons carrying negative charges and holes carrying positive charges in accordance with its sensitivity to an incident light beam, enabling the electrons to move to the negative electrode and the holes to move to the positive electrode because of a potential difference or charge concentration difference, thereby generating electrical power.

At present, conventional solar cells are essentially made of silicon, because of the high energy conversion efficiency of silicon, and come in the following categories: monocrystalline solar cells, polycrystalline solar cells, amorphous solar cells, and thin film solar cells. At present, the global solar cell market is dominated by monocrystalline solar cells and polycrystalline solar cells. However, the conventional silicon-based solar cells absorb a portion of the sunlight, that is, at wavelength of 400 nm-1000 nm, but do not absorb the ultraviolet and infrared of the sunlight.

Accordingly, it is imperative to enhance the energy conversion efficiency of solar cells.

### SUMMARY

It is an objective of the present invention to provide a protective film conducive to enhancing ultraviolet absorption and use without altering any existing solar cell manufacturing process and further provide a solar cell applicable to the protective film.

In order to achieve the above and other objectives, the present invention provides a protective film for use with a solar cell. The protective film is a protective coating formed on an anti-reflection layer of the solar cell, characterized in that the protective coating is made of one of an organic material and a phosphor-containing organic material, wherein the organic material is one selected from the group consisting of polyvinylidene fluoride (PVDF) resin, polymethyl methacrylate (PMMA) resin, silicone, and a combination of silicone and PVDF resin, wherein the phosphor in the phosphor-containing organic material is a down-converted phosphor. The down-converted phosphor is one of JQX(PO4)2:X3+ and JQX(PO4)2:X2+, X2+, wherein X denotes any rare earth metal, J denotes one of lithium, sodium, and potassium, and Q denotes any alkaline earth metal.

In an embodiment of the present invention, when the protective coating is made of the combination of silicone and PVDF resin, silicone and PVDF resin account for 70% and 30% of solid content of the protective coating, respectively.

In an embodiment of the present invention, when the protective coating is made of the phosphor-containing organic material, the phosphor and the organic material account for less than 10% and 10%˜100% of solid content of the phosphor-containing organic material, respectively.

In an embodiment of the present invention, the protective coating has a refractive index of 1.4˜1.8.

In an embodiment of the present invention, the protective coating has a thickness not larger than 30 μm.

In order to achieve the above and other objectives, the present invention further provides a solar cell applicable to the aforesaid protective film. The solar cell comprises: a semiconductor substrate, an anti-reflection layer on the semiconductor substrate, a rear conductive aluminum layer below the semiconductor substrate, a front conductive electrode, and a rear conductive electrode, characterized in that the protective film is a protective coating formed on the anti-reflection layer.

Accordingly, the present invention is characterized advantageously in that the protective film of the present invention augments the capability of a solar cell to absorb and use ultraviolet and enhances the photovoltaic conversion efficiency of the solar cell without altering any conventional solar cell manufacturing process.

### BRIEF DESCRIPTION

Objectives, features, and advantages of the present invention are hereunder illustrated with specific embodiments in conjunction with the accompanying drawings, in which:

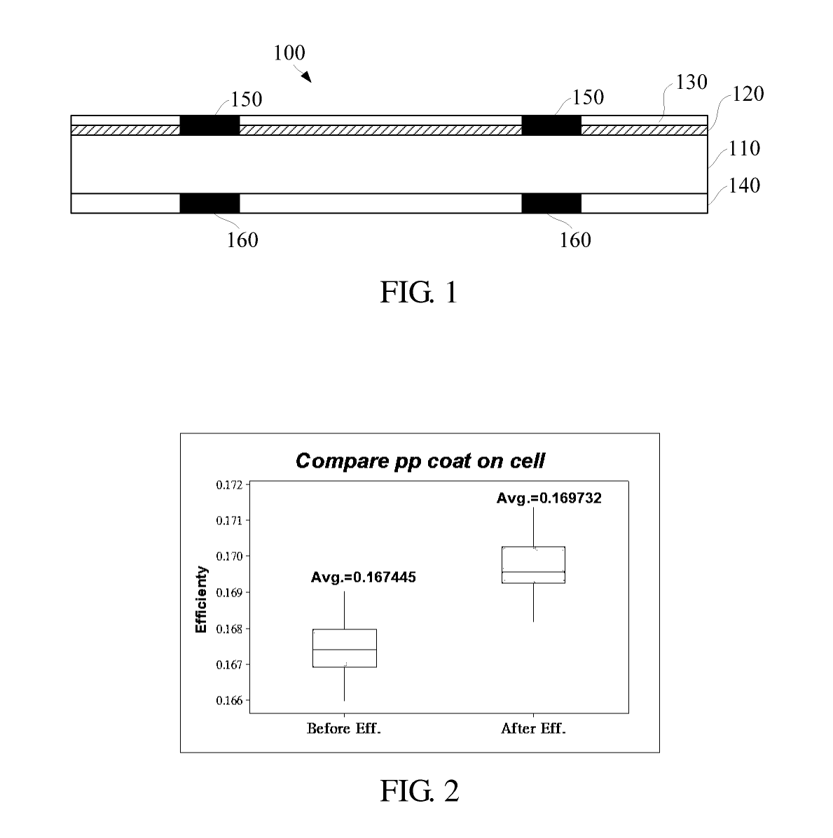

FIG. 1 is a schematic view of a solar cell according to an embodiment of the present invention; and

FIG. 2 is a schematic view of comparison of photovoltaic conversion efficiency between the solar cell without a protective coating and the solar cell with the protective coating.

### DETAILED DESCRIPTION

A protective film typically covers a solar cell exposed to the surroundings for a long period of time to render the solar cell insusceptible to damage that originates from the surroundings. The present invention provides a protective film which is a composite multifunction film. The protective film reflects incident light so as to reduce the amount of the incident light admitted into the solar cell.

Referring to FIG. 1, there is shown a schematic view of a solar cell 100 according to an embodiment of the present invention. The solar cell 100 comprises a semiconductor substrate 110, an anti-reflection layer 120, a protective coating 130, a rear conductive aluminum layer 140, a front conductive electrode 150, and a rear conductive electrode 160.

The semiconductor substrate 110 is for use in photovoltaic conversion to convert light energy of an incident beam into electrical energy.

Preferably, the anti-reflection layer 120 is made of an SiNx material, wherein the anti-reflection layer 120 and the protective coating 130 are collectively defined as an anti-reflection set of the solar cell 100 to reduce reflection and enhance light collection, by reducing the reflectivity of the light beams which fall on the semiconductor substrate 110 by means of the refractive indexes of the protective coating 130 and the anti-reflection layer 120. The reduction of the reflectivity of light beams by means of refractive indexes is attributable to the prior art and thus is not described in detail herein for the sake of brevity. Preferably, according to the present invention, the protective coating 130 has a refractive index of 1.4˜1.8. For example, the protective coating 130 is made of an organic polymer with a refractive index which falls within the range 1.4˜1.8, say, 1.4-1.6. Alternatively, for example, the protective coating 130 is made from LED-oriented silica gel as well as PVDF and epoxy resin for use in coating steel bars and steel plates. The anti-reflection layer 120 has a refractive index of 2.0˜2.2; in other words, the anti-reflection layer 120 is made of a material with a refractive index of 2.0˜2.2.

The front conductive electrode 150 penetrates the protective coating 130 and the anti-reflection layer 120 to connect to the semiconductor substrate 110. Furthermore, the rear conductive electrode 160 is opposite to the front conductive electrode 150 in terms of direction. The semiconductor substrate 110 is disposed between the front conductive electrode 150 and the rear conductive electrode 160, such that the rear conductive electrode 160 and the semiconductor substrate 110 are connected. Hence, the rear conductive aluminum layer 140 enables both the front conductive electrode 150 and the rear conductive electrode 160 to serve as a load in order for the solar cell 100 to generate electrical power.

The present invention is characterized in that the protective coating 130 is made of an organic material or a phosphor-containing organic material. The organic material is one selected from the group consisting of polyvinylidene fluoride (PVDF) resin, polymethyl methacrylate (PMMA) resin, silicone, and a combination of silicone and PVDF resin. The protective coating 130 made of the organic material has a melting point of 250° C. to 300° C., a density of 1.3 g/mL at 25° C., a refractive index of 1.69, and a transmittance of 94%. As regards the aforesaid combination of silicone and PVDF resin, preferably, silicone and PVDF resin account for 70% and 30% of the solid content of the protective coating 130, respectively, wherein the solid content of the protective coating 130 accounts for 80% to 90% of the total content of the protective coating 130, and the solvent accounts for the remainder of the protective coating 130. Alternatively, silicone and PVDF resin account for 50% and 50% of the solid content of the protective coating 130, respectively, or account for 30% and 70% of the solid content of the protective coating 130, respectively.

As regards the phosphor-containing organic material of the present invention, the phosphor (inorganic substance) and the organic material account for less than 10% and 10%˜100% of the solid content of the phosphor-containing organic material, respectively, and the solvent accounts for the remainder of the phosphor-containing organic material. The phosphor in the phosphor-containing organic material is a down-converted phosphor. The down-converted phosphor is “JQX(PO4)2:X3+” or “JQX(PO4)2:X2+, X2+”, wherein X denotes any rare earth metal, J denotes lithium, sodium, or potassium, and Q denotes any alkaline earth metal, such as Mg, Ca, Sr, Ba.

For example, a method of manufacturing the protective coating 130 from the phosphor-containing organic material comprises the steps of: mixing the down-converted phosphor and polymethyl methacrylate (PMMA) at a ratio of 1:10; applying the mixture to the anti-reflection layer 120; and curing the mixture on the anti-reflection layer 120. Upon completion of the above manufacturing process of the protective coating 130, the anti-reflection set which consists of the anti-reflection layer 120 and the protective coating 130 is capable of reducing the reflectivity of incident light and enhancing the absorption rate of ultraviolet. The aforesaid manufacturing process of the protective coating 130 for coating the anti-reflection layer 120 is, for example, performed by screen printing as described below.

After being manufactured from the phosphor-containing organic material at the aforesaid ratio and positioned on an organic material, a protective film for sole use with the organic material is applied to the anti-reflection layer 120 by screen printing in the steps of: adjusting the viscosity of the organic material by dissolving the organic material in a solvent gradually until the resultant viscosity of the organic material renders the organic material suitable for screen printing; coating the semiconductor substrate 110 fully with the organic material except a solar cell bus thereof; and baking the organic material at a high temperature, say, 180° C.˜250° C., to finalize the protective coating 130 which covers the semiconductor substrate 110, wherein the protective coating 130 which covers the semiconductor substrate 110 has a thickness of, preferably, 30 μm or less.

Referring to FIG. 2, there is shown a schematic view of comparison of photovoltaic conversion efficiency between the solar cell without a protective coating and the solar cell with the protective coating. As shown in the diagram, the solar cell without a protective coating has an initial photovoltaic conversion efficiency of 16.708%, and the solar cell with a protective coating has a photovoltaic conversion efficiency of 16.928%, thereby indicating that the organic material protective coating 130 of the present invention brings about a 0.2% increase in the photovoltaic conversion efficiency of solar cells. To this end, a related semiconductor manufacturing process only requires making a simple change thereto, that is, mixing the constituent ingredients of a material of which the protective coating 130 on the anti-reflection layer 120 is made, so as to enable ultraviolet to be partially converted into absorbable light and thus enhance the photovoltaic conversion efficiency. Furthermore, the photovoltaic conversion efficiency of solar cells will increase by 0.34%, if the protective coating 130 of the present invention contains a fluorescent material.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A protective film for use with a solar cell, being a protective coating, and being formed on an anti-reflection layer of the solar cell, characterized in that the protective coating is made of one of an organic material and a phosphor-containing organic material, wherein the organic material is one selected from the group consisting of polyvinylidene fluoride (PVDF) resin, polymethyl methacrylate (PMMA) resin, silicone, and a combination of silicone and PVDF resin, wherein the phosphor in the phosphor-containing organic material is a down-converted phosphor being one of JQX(PO₄)₂:X³⁺ and JQX(PO₄)₂:X²⁺, X²⁺, wherein X denotes any rare earth metal, J denotes one of lithium, sodium, and potassium, and Q denotes any alkaline earth metal.

2. The protective film of claim 1, wherein, when the protective coating is made of the combination of silicone and PVDF resin, silicone and PVDF resin account for 70% and 30% of solid content of the protective coating, respectively.

3. The protective film of claim 1, wherein, when the protective coating is made of the phosphor-containing organic material, the phosphor and the organic material account for less than 10% and 10%˜100% of solid content of the phosphor-containing organic material, respectively.

4. The protective film of claim 1, wherein the protective coating has a refractive index of 1.4˜4.8.

5. The protective film of claim 2, wherein the protective coating has a refractive index of 1.4˜1.8.

6. The protective film of claim 3, wherein the protective coating has a refractive index of 1.4˜1.8.

7. The protective film of claim 1, wherein the protective coating has a thickness not larger than 30 μm.

8. The protective film of claim 2, wherein the protective coating has a thickness not larger than 30 μm.

9. The protective film of claim 3, wherein the protective coating has a thickness not larger than 30 μm.

10. The protective film of claim 7, wherein the protective coating has a refractive index of 1.4˜1.8.

11. The protective film of claim 8, wherein the protective coating has a refractive index of 1.4˜1.8.

12. The protective film of claim 9, wherein the protective coating has a refractive index of 1.4˜1.8.

13. A solar cell for use with the protective film of claim 1, comprising a semiconductor substrate, an anti-reflection layer on the semiconductor substrate, a rear conductive aluminum layer below the semiconductor substrate, a front conductive electrode, and a rear conductive electrode, characterized in that the protective film is a protective coating formed on the anti-reflection layer.
